(19) United States
(12) Patent Application Publication
(10) Pub. No.: US 2025/0021011 A1
(43) Pub. Date: Jan. 16, 2025

(54) CONTROL DEVICE, OPTICAL SYSTEM, LITHOGRAPHY INSTALLATION AND METHOD

(71) Applicant: Carl Zeiss SMT GmbH, Oberkochen (DE)

(72) Inventor: Cornelius Richt, Aalen (DE)

(21) Appl. No.: 18/899,247

(22) Filed: Sep. 27, 2024

Related U.S. Application Data
(63) Continuation of application No. PCT/EP2023/058102, filed on Mar. 29, 2023.

(30) Foreign Application Priority Data
Apr. 1, 2022 (DE) 10 2022 203 257.8

(51) Int. Cl. G03F 7/00; G02B 26/08

(52) U.S. Cl. CPC G03F 7/70266; G02B 26/0833

(57) ABSTRACT

A control device for controlling and measuring an actuator for actuating an optical element of an optical system, comprises a voltage measuring unit, a current measuring unit, a first matched filter unit and a second matched filter unit. A method for controlling and measuring an actuator for actuating an optical element of an optical system comprises: providing a measurement voltage; providing a measurement current; estimating, via a first matched filter unit, a voltage amplitude and an associated phase of a measurement signal component; estimating, via a second matched filter unit, a current amplitude and an associated phase of the measurement signal component; and calculating an impedance of an actuator based on the estimated voltage amplitude, the estimated associated phase, the estimated current amplitude and the estimated associated phase.

### CROSS-REFERENCE TO RELATED APPLICATIONS

The present application is a continuation of, and claims benefit under 35 USC 120 to, international application No. PCT/EP2023/058102, filed Mar. 29, 2023, which claims benefit under 35 USC 119 of German Application No. 10 2022 203 257.8, filed Apr. 1, 2022. The entire disclosure of each of these applications is incorporated by reference herein.

### FIELD

The present disclosure relates to a control device for controlling and measuring an actuator of an optical system, to an optical system having such a control device, and to a lithography apparatus having such an optical system. The present disclosure also relates to a method for controlling and measuring an actuator of an optical system.

### BACKGROUND

Microlithography apparatuses are known which have actuatable optical elements, such as, for example, microlens element arrays or micromirror arrays. Microlithography is used to produce microstructured components, for example integrated circuits. The microlithography process is carried out using a lithography apparatus comprising an illumination system and a projection system.

Driven by the desire for ever smaller structures in the production of integrated circuits, EUV lithography apparatuses that use light with a wavelength in the range from 0.1 nm to 30 nm, such as 13.5 nm, are currently under development. Since most materials absorb light of this wavelength, EUV lithography apparatuses typically use reflective optics, which is to say mirrors, instead of—as previously—refractive optics, which is to say lens elements.

The image of a mask (reticle) illuminated via the illumination system is projected here via the projection system onto a substrate, for example a silicon wafer, which is coated with a light-sensitive layer (photoresist) and arranged in the image plane of the projection system, in order to transfer the mask structure to the light-sensitive coating of the substrate. The image representation of the mask on the substrate is able to be improved by way of actuatable optical elements. For example, wavefront aberrations during exposure, which result in magnified and/or blurred imaging, are able to be compensated for.

Such correction via the optical element can involve detection of the wavefront and signal processing in order to determine a respective position of an optical element which enables the wavefront to be corrected as desired. In the last step, the control signal for a respective optical element is amplified and output to the actuator of the optical element.

For example, a PMN actuator (PMN is lead magnesium niobate) can be used as actuator. A PMN actuator can enable distance positioning in the sub-micrometer range or sub-nanometer range. In this case, a DC voltage applied to the actuator, which has actuator elements stacked one on top of another, can lead to it experiencing a force that causes a specific linear expansion. The position set by way of the DC voltage (DC; Direct Current) can be adversely affected by external electromechanical crosstalk at the resonance points of the actuator controlled by the DC voltage which arise as a matter of principle. Owing to this electromechanical crosstalk, precise positioning might no longer able to be set in a stable manner. In this case, the mechanical resonances are generally all the greater the higher the applied DC voltage. The resonance points may also change in the long term, for example as a result of temperature drift or as a result of adhesive drift if the mechanical linking of the adhesive material changes, or as a result of hysteresis or ageing. For example, an impedance measurement would be helpful in this context.

However, conventional impedance measuring equipment is often too costly and furthermore does not have an inline capability, i.e. they are regularly not able to be used in a lithography apparatus. Further, integrated impedance measuring bridges, which are usually designed for excessively high impedance values, can prove to be unsuitable for the present application in a lithography apparatus since the impedance value range of interest here encompasses several orders of magnitude and the region of interest is only a fraction of the total range.

It is also known practice to control the actuators of a lithography apparatus via a respective control signal which has a low-frequency control component for controlling the actuator and a higher-frequency measurement signal component for measuring the actuator. Conventionally, such a control signal is amplified with a gain that is uniform over the frequency via an output stage and applied to the actuator as control voltage.

The control voltage and the arising current can then be measured by other circuit parts. However, the measured signals, specifically the measurement current in this case, can be subject to significant noise. As a result, the desired accuracy might not be readily achieved.

The conventional approach for calculating the impedance of the actuator by way of the frequency lies in performing a respective Fourier transform on the measured signals and dividing these in the frequency domain following the transform. However, this procedure can include: evaluation by way of the Fourier transform exhibits little robustness in relation to noise; the Fourier transform might not always performed on the entire frequency spectrum, even if the measurement signal contains only a single frequency or small frequency range; evaluation by way of the Fourier transform can involve a very long measurement time, especially at low frequencies; and the frequency of the excitation signal should fit the frequency points of the Fourier transform or the sampling rate of the measurement signal.

### SUMMARY

The present disclosure seeks to improve the control and measurement of an actuator of an optical system.

According to a first aspect, a control device is proposed for controlling and measuring an actuator for actuating an optical element of an optical system. The control device comprises:
a voltage measuring unit for providing a measurement voltage indicative of a time-dependent voltage of the actuator controlled via an excitation signal on the basis of a specific model, the excitation signal comprising at least one sinusoidal measurement signal component for measuring the impedance of the actuator,
a current measuring unit for providing a measurement current indicative of a time-dependent current of the actuator controlled via the excitation signal,
a first matched filter unit for estimating a voltage amplitude and an associated phase of the measurement signal component arising at the actuator using the measurement voltage provided and the specific model of the excitation signal,
a second matched filter unit for estimating a current amplitude and an associated phase of the measurement signal component arising at the actuator using the measurement current provided and the specific model of the excitation signal, and
a calculation unit configured to calculate the impedance of the actuator on the basis of the estimated voltage amplitude, the estimated associated phase, the estimated current amplitude and the estimated associated phase.

As a result of calculating the impedance of the actuator, the present control device can enable a quick and inline-capable determination of the impedance behavior of the actuator, such as an impedance determination of the actuator installed in the lithography apparatus.

The present control device for measuring the actuator can manage without the comparatively slow use of a Fourier transform. By contrast, the actuator is excited using an excitation signal whose model, on which the excitation signal is based, is known. This model or specific model is known not only to the signal generator for generating the excitation signal but also to the first matched filter unit and the second matched filter unit in the present case. As a result of the model of the excitation signal being known to the first matched filter unit and the second matched filter unit, the voltage amplitude and its associated phase and also the current amplitude and its associated phase can be estimated quickly and accurately. The calculation unit then can calculate the impedance of the actuator on the basis of this very fast and accurate determination. As a result of using the model for the present estimates and calculations for determining the impedance, it is possible to avoid a conventional measurement of the entire spectrum and subsequent search for the excitation signal.

The determined impedance behavior of the actuator can form the basis for implementing suitable remedies or countermeasures, such as an active inline calibration or inline damping, also via the control signal.

For example, the provision of a measurement voltage by the voltage measuring unit is formed by measurement or by equating the measurement voltage to the control signal or by deriving the measurement voltage from the control signal in the case that the control signal is a voltage signal.

The provision of a measurement current is formed for example by measurement or by equating the measurement current to the control signal or by deriving the measurement current from the control signal in the case that the control signal is a current signal.

The actuator can be a capacitive actuator, for example a PMN actuator (PMN is lead magnesium niobate) or a PZT actuator (PZT is lead zirconate titanate) or a LiNbO₃ actuator (lithium niobate). The actuator is configured, for example, to actuate an optical element of the optical system. Examples of such an optical element include lens elements, mirrors and adaptive mirrors.

The optical system can be a projection optical unit of the lithography apparatus or projection exposure apparatus. However, the optical system can also be an illumination system. The projection exposure apparatus can be an EUV lithography apparatus. EUV stands for “extreme ultraviolet” and refers to a wavelength of the working light of between 0.1 nm and 30 nm. The projection exposure apparatus can also be a DUV lithography apparatus. DUV stands for “deep ultraviolet” and refers to a wavelength of the working light of between 30 nm and 250 nm.

According to an embodiment, the first matched filter unit is configured to use a linear least squares estimate to estimate the voltage amplitude and the associated phase of the measurement signal component arising at the actuator using the measurement voltage provided and the specific model of the excitation signal.

According to an embodiment, the first matched filter unit is configured to carry out the linear least squares estimate on the basis of a Moore-Penrose inverse, the Moore-Penrose inverse comprising coefficients suitable for the compensation of a transfer function of the voltage measuring unit.

Compensating the transfer function of the voltage measuring unit can render the provision of the measurement voltage more accurate, and consequently the impedance of the actuator is calculable even more accurately.

According to an embodiment, the second matched filter unit is configured to use a linear least squares estimate to estimate the current amplitude and the associated phase of the measurement signal component arising at the actuator using the measurement current provided and the specific model of the excitation signal.

According to an embodiment, the second matched filter unit is configured to carry out the linear least squares estimate on the basis of a Moore-Penrose inverse, the Moore-Penrose inverse comprising coefficients suitable for the compensation of a transfer function of the current measuring unit.

Compensating the transfer function of the current measuring unit renders the provision of the measurement current more accurate, and consequently the impedance of the actuator is calculable even more accurately.

According to an embodiment, the control device comprises a signal generator configured to provide the excitation signal having at least the sinusoidal measurement signal component for measuring the impedance of the actuator.

According to an embodiment, the specific model of the excitation signal is determined by the following equation:

$$y ( t ) = a * sin ( 2 π ft + φ ) ,$$

where y(t) denotes the excitation signal, a denotes the amplitude, f denotes the frequency, t denotes the time and φ denotes the phase.

According to an embodiment, the signal generator is configured to provide the excitation signal in such a way that this comprises a control signal component for setting a specific position of the controlled actuator and the sinusoidal measurement signal component for measuring the impedance of the actuator.

According to an embodiment, the specific model of the excitation signal is determined by the following equation:

$$y ( t ) = O + a * sin ( 2 π ft + φ ) ,$$

where y(t) denotes the excitation signal, O denotes the control signal component, a denotes the amplitude, f denotes the frequency, t denotes the time and φ denotes the phase.

According to an embodiment, the signal generator is configured to provide the excitation signal as a broadband excitation signal having a plurality of sinusoidal measurement signal components for simultaneously measuring the actuator at a plurality of different frequencies.

This can allow the actuator to be measured at a multiplicity of different frequencies, and appropriate measures can be derived for the different frequencies in differentiated fashion.

According to an embodiment, the calculation unit is configured to calculate the complex impedance of the actuator via a phase shift between the phase associated with the voltage amplitude and the phase associated with the current amplitude and a quotient between the voltage amplitude and the current amplitude. In this context, the complex impedance can be formed by the quotient of the voltage amplitude and current amplitude, and the phase difference.

According to an embodiment, the control device comprises a control unit coupled between the signal generator and the actuator. In this case, the control unit can be configured to output to the actuator a time-dependent control voltage for controlling the actuator on the basis of the excitation signal provided by the signal generator.

The control device of this embodiment can also be referred to as an amplifier stage for controlling an actuator with an integrated determination of current, voltage and impedance.

According to an embodiment, the control unit has a frequency-dependent first transfer function and is configured thereby to amplify the excitation signal comprising at least a first frequency range and a second frequency range to form the control voltage for the actuator, in such a way that the first frequency range experiences a higher gain vis-à-vis the second frequency range by a specific factor. Further, the voltage measuring unit can be configured to provide the measurement voltage using a second transfer function that is based on an inverse of the first transfer function. The current measuring unit can be configured to provide the measurement current using a third transfer function that is based on an inverse of the first transfer function. In this case, the first matched filter unit can be configured to carry out the linear least squares estimate on the basis of a Moore-Penrose inverse, the Moore-Penrose inverse comprising coefficients suitable for the compensation of the second transfer function of the voltage measuring unit. Accordingly, the second matched filter unit can be configured to carry out the linear least squares estimate on the basis of a Moore-Penrose inverse, the Moore-Penrose inverse comprising coefficients suitable for the compensation of the third transfer function of the current measuring unit.

The present embodiment of the control device can enable high gain in the first frequency range for controlling the actuator and, at the same time, a high resolution in the second frequency range for measuring the actuator, for example for measuring the impedance of the actuator. In this case, the portion of the control voltage in the first frequency range serves to control the actuator, for example to control the deflection thereof. In the process, the first frequency range experiences a higher gain vis-à-vis the second frequency range in order to suitably control the actuator. Prior to the respective measurement, i.e. prior to the voltage measurement and the current measurement, the first frequency range is damped and the second frequency range is amplified so that a high resolution for measuring the actuator is provided in the second frequency range.

According to an embodiment, the first frequency range is located between 0 Hz and 1 kHz, such as between 0 Hz and 500 Hz, for example between 0 Hz and 300 Hz.

According to an embodiment, the second frequency range is located between 5 kHz and 100 kHz, such as between 10 kHz and 100 kHz, for example between 10 kHz and 60 kHz.

According to an embodiment, the specific factor is between 100 and 2000, such as between 500 and 1500, for example between 800 and 1200.

According to an embodiment, the control unit comprises an amplifier circuit, such as a differential amplifier.

The respective unit, for example the calculation unit, can be implemented by way of hardware technology and/or also software technology. In the case of a hardware implementation, the unit can be in the form of a device or part of a device, for example a computer or a microprocessor or part of the control apparatus. In the case of a software implementation, the unit can be in the form of a computer program product, a function, a routine, part of a program code or an executable object.

According to a second aspect, an optical system having a number of actuatable optical elements is proposed, with each of the actuatable optical elements of the number being assigned an actuator and each actuator being assigned a control device for controlling the actuator according to the first aspect or according to one of the embodiments of the first aspect.

The optical system comprises, for example, a micromirror array and/or a microlens element array having a multiplicity of optical elements that are actuatable independently of one another.

In embodiments, groups of actuators can be defined, wherein all actuators of a group are assigned the same control device.

According to an embodiment, the optical system is in the form of an illumination optical unit or in the form of a projection optical unit of a lithography apparatus.

According to an embodiment, the optical system comprises a vacuum housing, in which the actuatable optical elements, the assigned actuators and the control device are arranged.

According to a third aspect, a lithography apparatus is proposed, which comprises an optical system according to the second aspect or according to one of the embodiments of the second aspect.

The lithography apparatus is for example an EUV lithography apparatus, the working light of which is in a wavelength range of 0.1 nm to 30 nm, or a DUV lithography apparatus, the working light of which is in a wavelength range of 30 nm to 250 nm.

According to a fourth aspect, a method is proposed for controlling and measuring an actuator for actuating an optical element of an optical system. The method comprises the following steps:
providing a measurement voltage indicative of a time-dependent voltage of the actuator controlled via an excitation signal on the basis of a specific model, the excitation signal comprising at least one sinusoidal measurement signal component for measuring the impedance of the actuator,
providing a measurement current indicative of a time-dependent current of the actuator controlled via the excitation signal,
estimating, via a first matched filter unit, a voltage amplitude and an associated phase of the measurement signal component arising at the actuator using the measurement voltage provided and the specific model of the excitation signal,
estimating, via a second matched filter unit, a current amplitude and an associated phase of the measurement signal component arising at the actuator using the measurement current provided and the specific model of the excitation signal, and
calculating the impedance of the actuator on the basis of the estimated voltage amplitude, the estimated associated phase, the estimated current amplitude and the estimated associated phase.

The embodiments described for the proposed control device apply correspondingly to the proposed method, and vice versa. Furthermore, the definitions and explanations in relation to the control device also apply correspondingly to the proposed method.

“A(n)” should not necessarily be understood as a restriction to exactly one element in the present case. Rather, a plurality of elements, for example two, three or more, may also be provided. Nor should any other numeral used here be understood to the effect that there is a restriction to exactly the stated number of elements. Instead, unless indicated otherwise, numerical deviations upward and downward are possible.

Further possible implementations of the disclosure also encompass not explicitly mentioned combinations of features or embodiments that are described above or hereinafter with respect to the exemplary embodiments. In this case, a person skilled in the art will also add individual aspects as improvements or supplementations to the respective basic form of the disclosure.

Various configurations and aspects of the disclosure are the subject of the claims and also of the exemplary embodiments of the disclosure that are described hereinafter. The disclosure is explained in greater detail hereinafter on the basis of certain embodiments with reference to the accompanying figures.

### BRIEF DESCRIPTION OF THE DRAWINGS

FIG. 1 shows a schematic meridional section of a projection exposure apparatus for EUV projection lithography;

FIG. 2 shows a schematic illustration of an embodiment of an optical system;

FIG. 3 shows a schematic block diagram of an embodiment of a control device for controlling and measuring an actuator for actuating an optical element of an optical system; and

FIG. 4 shows a schematic view of an embodiment of a method for controlling and measuring an actuator for actuating an optical element of an optical system.

### DETAILED DESCRIPTION

Unless indicated otherwise, elements that are identical or functionally identical have been provided with the same reference signs in the figures. Furthermore, it should be noted that the illustrations in the figures are not necessarily true to scale.

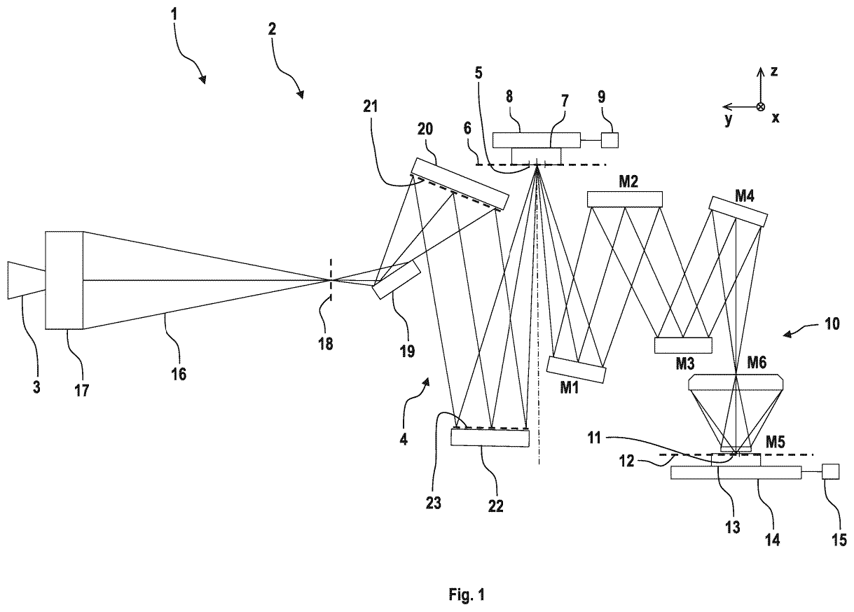

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs in the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement firstly of the reticle 7 by way of the reticle displacement drive 9 and secondly of the wafer 13 by way of the wafer displacement drive 15 can be implemented so as to be mutually synchronized.

The light source 3 is an EUV radiation source. The light source 3 emits for example EUV radiation 16, which is also referred to below as used radiation, illumination radiation or illumination light. For example, the used radiation 16 has a wavelength in the range between 5 nm and 30 nm. The light source 3 can be a plasma source, for example an LPP (laser produced plasma) source or a GDPP (gas discharge produced plasma) source. It can also be a synchrotron-based radiation source. The light source 3 can be a free electron laser (FEL).

The illumination radiation 16 emanating from the light source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 can be structured and/or coated, firstly to optimize its reflectivity for the used radiation and secondly to suppress extraneous light.

The illumination radiation 16 propagates through an intermediate focus in an intermediate focal plane 18 downstream of the collector 17. The intermediate focal plane 18 can represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect that goes beyond the purely deflecting effect. In an alternative to that or in addition, the deflection mirror 19 can be designed as a spectral filter that separates a used light wavelength of the illumination radiation 16 from extraneous light at a different wavelength. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are shown in FIG. 1 by way of example.

The first facets 21 can be embodied as macroscopic facets, for example as rectangular facets or as facets with an arcuate or part-circular edge contour. The first facets 21 can be in the form of plane facets or alternatively in the form of convexly or concavely curved facets.

As is known for example from DE 10 2008 009 600 A1, the first facets 21 themselves can also each be composed of a multiplicity of individual mirrors, for example a multiplicity of micromirrors. For example, the first facet mirror 20 can be in the form of a microelectromechanical system (MEMS system). For details, reference is made to DE 10 2008 009 600 A1.

The illumination radiation 16 propagates horizontally, i.e. in the y-direction y, between the collector 17 and the deflection mirror 19.

In the beam path of the illumination optical unit 4, a second facet mirror 22 is disposed downstream of the first facet mirror 20. Provided the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or else hexagonal periphery, or can alternatively be facets composed of micromirrors. In this regard, reference is likewise made to DE 10 2008 009 600 A1.

The second facets 23 can have plane or, alternatively, convexly or concavely curved reflection surfaces.

The illumination optical unit 4 consequently forms a doubly faceted system. This fundamental principle is also referred to as a fly's eye integrator.

It might be desirable to arrange the second facet mirror 22 not exactly in a plane that is optically conjugate to a pupil plane of the projection optical unit 10. For example, the second facet mirror 22 can be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or else indeed the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 might be arranged in the beam path between the second facet mirror 22 and the object field 5. The transfer optical unit might have exactly one mirror or, alternatively, also two or more mirrors, which are arranged in succession in the beam path of the illumination optical unit 4. The transfer optical unit might for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 may also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be in the form of free-form surfaces without an axis of rotational symmetry. Alternatively, the reflection surfaces of the mirrors Mi can be in the form of aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

For example, the projection optical unit 10 can have an anamorphic design. It has for example different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x- and y-directions x, y are known from US 2018/0074303 A1.

In each case one of the second facets 23 is assigned to exactly one of the first facets 21 for forming in each case an illumination channel for illuminating the object field 5. This can for example result in illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are in each case imaged onto the reticle 7 in a manner overlaid on one another for the purpose of illuminating the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, for example the subset of the second facets 23, which guide light. This intensity distribution is also referred to as illumination setting or illumination pupil filling.

A likewise preferred pupil uniformity in the region of defined illuminated portions of an illumination pupil of the illumination optical unit 4 may be achieved by a redistribution of the illumination channels.

Further aspects and details of the illumination of the object field 5 and for example of the entrance pupil of the projection optical unit 10 are described below.

The projection optical unit 10 may have a homocentric entrance pupil for example. The latter can be accessible. It can also be inaccessible.

The entrance pupil of the projection optical unit 10 regularly cannot be exactly illuminated with the second facet mirror 22. In the case of projection optical unit 10 imaging, which images the center of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. For example, this area exhibits a finite curvature.

It may be the case that the projection optical unit 10 has different positions of the entrance pupil for the tangential beam path and for the sagittal beam path. In this case, an imaging element, for example an optical component of the transfer optical unit, should be provided between the second facet mirror 22 and the reticle 7. With the aid of this optical element, the different poses of the tangential entrance pupil and the sagittal entrance pupil can be taken into account.

In the arrangement of the component parts of the illumination optical unit 4 shown in FIG. 1, the second facet mirror 22 is arranged in an area conjugate to the entrance pupil of the projection optical unit 10. The first facet mirror 20 is arranged tilted in relation to the object plane 6. The first facet mirror 20 is arranged tilted in relation to an arrangement plane defined by the deflection mirror 19. The first facet mirror 20 is arranged tilted in relation to an arrangement plane defined by the second facet mirror 22.

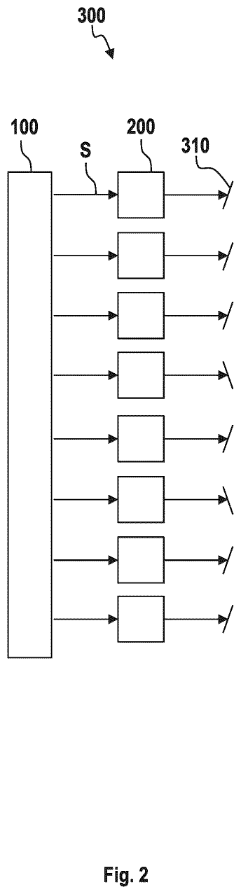

FIG. 2 shows a schematic illustration of an embodiment of an optical system 300 for a lithography apparatus or projection exposure apparatus 1, as shown in FIG. 1 for example. Additionally, the optical system 300 of FIG. 2 may also be used in a DUV lithography apparatus for example.

The optical system 300 of FIG. 2 has a plurality of actuatable optical elements 310. The optical system 300 is designed here as a micromirror array, wherein the optical elements 310 are micromirrors. Each micromirror 310 is actuatable via an assigned actuator 200. By way of example, a respective micromirror 310 can be tilted about two axes and/or displaced in one, two, or three spatial axes via the assigned actuator 200. The reference signs only of the topmost row of these elements are depicted, for reasons of clarity.

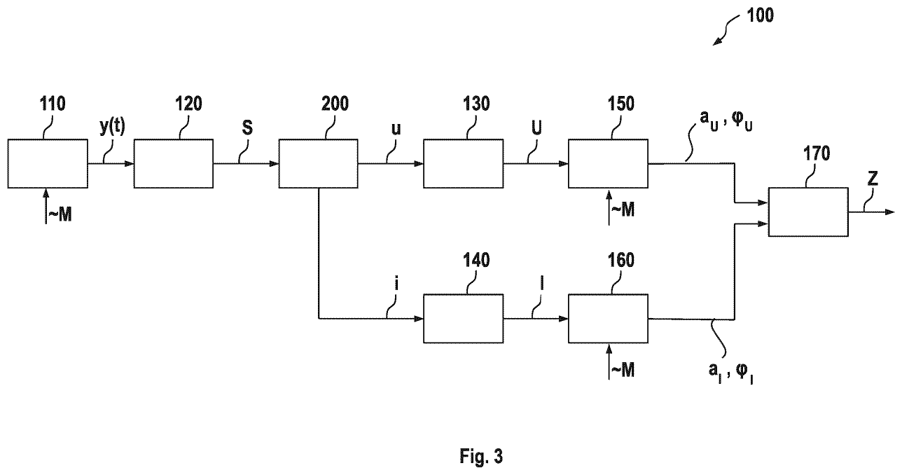

The control device 100 controls the respective actuator 200, for example with a control voltage S. This sets a position of the respective micromirror 310. The control device 100 is described with reference to FIG. 3 for example.

FIG. 3 illustrates a schematic block diagram of an embodiment of a control device 100 for controlling and measuring an actuator 200 for actuating an optical element 300 of an optical system 300.

The control device 100 according to FIG. 3 comprises a signal generator 110, a control unit 120 coupled to the signal generator 110 and serving to control the actuator 200, a voltage measuring unit 130 coupled to the actuator 200, a current measuring unit 140 coupled to the actuator 200, a first matched filter unit 150, a second matched filter unit 160 and a calculation unit 170.

The signal generator 110 is configured to provide an excitation signal y(t) based on a specific model M and having at least one sinusoidal measurement component for measuring the impedance Z of the actuator 200. Presently, “sinusoidal” should also be understood to mean “cosine curve-shaped” for example.

For the case that the excitation signal y(t) comprises only a sinusoidal measurement signal component for measuring the impedance Z of the actuator 200, the model M of the excitation signal y(t) is determined by the following equation:

$$y ( t ) = a * sin ( 2 π ft + φ ) .$$

In the equation above, y(t) denotes the excitation signal, a denotes the amplitude, f denotes the frequency, t denotes the time and φ denotes the phase.

However, in embodiments, the signal generator 110 is also configured to provide the excitation signal y(t) in such a way that the excitation signal y(t) comprises a control signal component for setting a specific position of the controlled actuator 200 and the sinusoidal measurement signal component for measuring the impedance Z of the actuator 200. In these cases, the model M of the excitation signal y(t) is determined by the following equation:

$$y ( t ) = O + a * sin ( 2 π ft + φ ) ,$$

where y(t) denotes the excitation signal, O denotes the control signal component, a denotes the amplitude, f denotes the frequency, t denotes the time and φ denotes the phase.

Moreover, in embodiments, the signal generator 110 can be configured to provide the excitation signal y(t) as a broadband excitation signal having a plurality of sinusoidal measurement signal components for simultaneously measuring the actuator 200 at a plurality of different frequencies. In these cases, too, the excitation signal y(t) may additionally comprise a control signal component for setting a specific position of the controlled actuator 200.

As explained above, the control unit 120 is disposed downstream of the signal generator 110. The control unit 120 is coupled between the signal generator 110 and the actuator 200 and receives the excitation signal y(t) provided by the signal generator 110. Here, the control unit 120 is configured to output to the actuator 200 a time-dependent control voltage S for controlling the actuator 200 on the basis of the excitation signal y(t) provided by the signal generator 110.

The voltage measuring unit 130 is coupled to the actuator 200 and configured to provide a measurement voltage U. The measurement voltage U is indicative of a time-dependent voltage u of the actuator 200 controlled via the excitation signal y(t). The actuator 200 being controlled via the excitation signal y(t) in this case comprises the generation of the control voltage S on the basis of the excitation signal y(t), and the subsequent control of the actuator 200 using the generated control voltage S.

The first matched filter unit 150 disposed downstream of the voltage measuring unit 130 is configured to estimate a voltage amplitude a_{U} and an associated phase φ_{U} of the measurement signal component arising at the actuator 200 using the measurement voltage U provided and the specific model M of the excitation signal y(t). For example, the first matched filter unit 150 uses a linear least squares estimate to provide this estimate. In this case, the first matched filter unit 150 can be configured to carry out the linear least squares estimate on the basis of a

Moore-Penrose inverse. In this case, the Moore-Penrose inverse comprises coefficients which are suitable for the compensation of a transfer function of the voltage measuring unit 130.

The current measuring unit 140 is coupled to the actuator 200 and configured to provide a measurement current I. The measurement current I is indicative of a time-dependent current i of the actuator 200 controlled via the excitation signal y(t). Disposed downstream of the current measuring unit 140 there is a second matched filter unit 160 configured to estimate a current amplitude a_{I} and an associated phase φ_{I} of the measurement signal component arising at the actuator 200 using the measurement current I provided and the specific model M of the excitation signal y(t). To provide this estimate, the second matched filter unit 160—in a manner analogous to the first matched filter unit 150—uses a linear least-squares estimate.

In this case, the second matched filter unit 160 is configured for example to carry out the linear least squares estimate on the basis of a Moore-Penrose inverse. This Moore-Penrose inverse comprises coefficients which are suitable for the compensation of the transfer function of the current measuring unit 140.

The calculation unit 170 is disposed downstream of the first matched filter unit 150 and the second matched filter unit 160 and configured to calculate the impedance Z of the actuator 200 on the basis of the estimated voltage amplitude a_{U}, the estimated associated phase φ_{U}, the estimated current amplitude a_{I} and the estimated associated phase φ_{I}. In this case, the calculation unit 170 calculates, for example, the complex impedance Z of the actuator 200 via a phase shift between the phase φ_{U} associated with the voltage amplitude a_{U} and the phase φ_{I} associated with the current amplitude a_{I} and a quotient between the voltage amplitude a_{U} and the current amplitude a_{I}.

In embodiments, the control unit 120 has a frequency-dependent first transfer function and is configured thereby to amplify the excitation signal y(t) comprising at least a first frequency range and a second frequency range to form the control voltage S for the actuator 200, in such a way that the first frequency range experiences a higher gain vis-à-vis the second frequency range by a specific factor. For example, the first frequency range is located between 0 Hz and 1 kHz, such as between 0 Hz and 500 Hz, for example between 0 Hz and 300 Hz. The second frequency range is located between 5 kHz and 100 kHz, such as between 10 kHz and 100 kHz, for example between 10 kHz and 60 kHz, for example. For example, the specific factor is between 100 and 2000, such as between 500 and 1500, such as between 800 and 1200.

In these embodiments, the voltage measuring unit 120 is configured to provide the measurement voltage U using a second transfer function that is based on an inverse of the first transfer function, and the current measuring unit 130 is configured to provide the measurement current I using a third transfer function that is based on an inverse of the first transfer function. In that case, the first matched filter unit 150 can be configured to carry out the linear least squares estimate on the basis of a Moore-Penrose inverse, the Moore-Penrose inverse comprising coefficients configured for the compensation of the second transfer function of the voltage measuring unit 130. Accordingly, the second matched filter unit 160 is configured to carry out the linear least squares estimate on the basis of a Moore-Penrose inverse, the Moore-Penrose inverse comprising coefficients suitable for the compensation of the third transfer function of the current measuring unit 130.

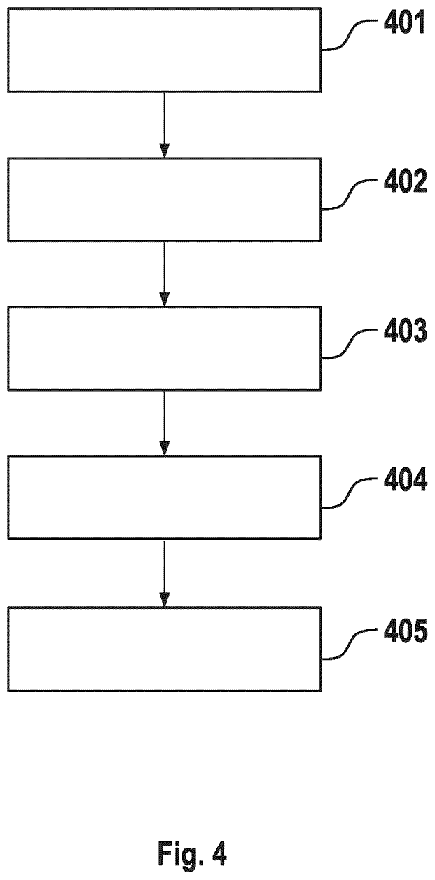

FIG. 4 shows a schematic view of an embodiment of a method for controlling and measuring an actuator 200 for actuating an optical element 310 of an optical system 300. An example of an optical system 300 is depicted in FIG. 2. For example, the optical system 300 is a part of a lithography apparatus 1, as depicted in FIG. 1 for example. The method according to FIG. 4 is executable by, for example, a control device 100, as shown by way of example in FIG. 3, and comprises steps 401 to 405:

In step 401, a measurement voltage U is provided, the latter being indicative of a time-dependent voltage u of the actuator 200 controlled via an excitation signal y(t) on the basis of a specific model M. In this case, the excitation signal y(t) comprises at least a sinusoidal measurement signal component for measuring the impedance Z of the actuator 200.

In step 402, a measurement current I is provided, the latter being indicative of a time-dependent current i of the actuator 200 controlled via the excitation signal y(t).

In step 403, an estimate is provided, via a first matched filter unit 150, of a voltage amplitude a_{U} and an associated phase φ_{U} of the measurement signal component arising at the actuator 200 using the measurement voltage U provided and the specific model M of the excitation signal y(t).

In step 404, an estimate is provided, via a second matched filter unit 160, of a current amplitude a_{I} and an associated phase φ_{I} of the measurement signal component arising at the actuator 200 using the measurement current I provided and the specific model M of the excitation signal y(t).

In step 405, the impedance Z of the actuator 200 is calculated on the basis of the estimated voltage amplitude a_{U}, the estimated associated phase φ_{U}, the estimated current amplitude a_{I} and the estimated associated phase φ_{I}.

Although the present disclosure has been described on the basis of exemplary embodiments, it can be modified in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Control device
110 Signal generator
120 Control unit
130 Voltage measuring unit
140 Current measuring unit
150 First matched filter unit
160 Second matched filter unit
170 Calculation unit
200 Actuator
300 Optical system
310 Optical element
401 Method step
402 Method step
403 Method step
404 Method step
405 Method step
a_{I} Current amplitude
a_{U} Voltage amplitude
I Measurement current
i Current of the actuator
M Model
M1 Mirror
M2 Mirror
M3 Mirror
M4 Mirror
M5 Mirror
MC Mirror
S Control voltage
U Measurement voltage
u Voltage of the actuator
y(t) Excitation signal
Z Impedance
φ_{I} Phase
φ_{U} Phase

What is claimed is:

1. A control device, comprising:
a voltage measuring unit configured to provide a measurement voltage indicative of a time-dependent voltage of an actuator controlled via an excitation signal based on a specific model, the excitation signal comprising a sinusoidal measurement signal component configured to measure an impedance of the actuator;
a current measuring unit configured to provide a measurement current indicative of a time-dependent current of the actuator controlled via the excitation signal;
a first matched filter unit configured to estimate a voltage amplitude and an associated phase of the measurement signal component arising at the actuator based on the measurement voltage provided and the specific model of the excitation signal;
a second matched filter unit configured to estimate a current amplitude and an associated phase of the measurement signal component arising at the actuator based on the measurement current provided and the specific model of the excitation signal; and
a calculation unit configured to calculate the impedance of the actuator based on the estimated voltage amplitude, the estimated associated phase, the estimated current amplitude and the estimated associated phase.

2. The control device of claim 1, wherein the first matched filter unit is configured to use a linear least squares estimate to estimate the voltage amplitude and the associated phase of the measurement signal component arising at the actuator using the measurement voltage provided and the specific model of the excitation signal.

3. The control device of claim 2, wherein the first matched filter unit is configured to carry out the linear least squares estimate based on a Moore-Penrose inverse, the Moore-Penrose inverse comprising coefficients suitable for the compensation of a transfer function of the voltage measuring unit.

4. The control device of claim 1, wherein the second matched filter unit is configured to use a linear least squares estimate to estimate the current amplitude and the associated phase of the measurement signal component arising at the actuator using the measurement current provided and the specific model of the excitation signal.

5. The control device of claim 4, wherein the second matched filter unit is configured to carry out the linear least squares estimate on the basis of a Moore-Penrose inverse, the Moore-Penrose inverse comprising coefficients suitable for the compensation of a transfer function of the current measuring unit.

6. The control device of claim 1, further comprising a signal generator configured to provide the excitation signal.

7. The control device of claim 6, wherein the signal generator is configured to provide the excitation signal so that the excitation signal comprises a control signal component configured to set a specific position of the controlled actuator and the sinusoidal measurement signal component for measuring the impedance of the actuator.

8. The control device of claim 7, wherein the specific model of the excitation signal is determined by the following equation:
$$y ( t ) = O + a * sin ( 2 π ft + φ ) ,$$
where y(t) denotes the excitation signal, O denotes the control signal component, a denotes the amplitude, f denotes the frequency, t denotes the time and φ denotes the phase.

9. The control device of claim 6, further comprising a control unit coupled to the signal generator and the actuator, wherein the control unit is configured to output to the actuator a time-dependent control voltage configured to control the actuator based on the excitation signal provided by the signal generator.

10. The control device of claim 9, wherein:
the first matched filter unit is configured to use a linear least squares estimate to estimate the voltage amplitude and the associated phase of the measurement signal component arising at the actuator using the measurement voltage provided and the specific model of the excitation signal;
the second matched filter unit is configured to use a linear least squares estimate to estimate the current amplitude and the associated phase of the measurement signal component arising at the actuator using the measurement current provided and the specific model of the excitation signal;
the control unit comprises a frequency-dependent first transfer function and the control unit is configured thereby to amplify the excitation signal comprising a first frequency range and a second frequency range to form the control voltage for the actuator so that the first frequency range experiences a higher gain vis-à-vis the second frequency range by a specific factor;
the voltage measuring unit is configured to provide the measurement voltage based on a second transfer function that is based on an inverse of the first transfer function;
the current measuring unit is configured to provide the measurement current based on a third transfer function that is based on an inverse of the first transfer function.

11. The control device of claim 10, wherein:
the first matched filter unit is configured to carry out the linear least squares estimate on the basis of a Moore-Penrose inverse, the Moore-Penrose inverse comprising coefficients suitable for the compensation of the second transfer function of the voltage measuring unit; and
the second matched filter unit is configured to carry out the linear least squares estimate on the basis of a Moore-Penrose inverse, the Moore-Penrose inverse comprising coefficients suitable for the compensation of the third transfer function of the current measuring unit (140).

12. The control device of claim 1, wherein the specific model of the excitation signal is determined by the following equation:
$$y ( t ) = a * sin ( 2 π ft + φ ) ,$$
where y(t) denotes the excitation signal, a denotes the amplitude, f denotes the frequency, t denotes the time, and φ denotes the phase.

13. The control device of claim 1, wherein the signal generator is configured to provide the excitation signal as a broadband excitation signal comprising a plurality of sinusoidal measurement signal components configured to simultaneously measure the actuator at a plurality of different frequencies.

14. The control device of claim 1, wherein the calculation unit is configured to calculate the complex impedance of the actuator based on a phase shift between the phase associated with the voltage amplitude and the phase associated with the current amplitude and a quotient between the voltage amplitude and the current amplitude.

15. An optical system, comprising:
an optical element;
an actuator; and
a control device according to claim 1,
wherein the actuator is configured to actuate the optical element.

16. The optical system of claim 15, wherein the optical system is lithography illumination optical unit, or a lithography projection optical unit.

17. An optical system, comprising:
a plurality of optical elements;
a plurality of actuators; and
a plurality of control devices according to claim 1,
wherein each actuator has a corresponding control device, and each actuator is configured to actuate a corresponding optical element.

18. The optical system of claim 17, wherein the optical system is lithography illumination optical unit, or a lithography projection optical unit.

19. An apparatus, comprising:
a plurality of optical elements;
a plurality of actuators; and
a plurality of control devices according to claim 1,
wherein each actuator has a corresponding control device, each actuator is configured to actuate a corresponding optical element, and the apparatus is a lithography apparatus.

20. A method of controlling and measuring an actuator configured to actuate an optical element of an optical system, the method comprising:
providing a measurement voltage indicative of a time-dependent voltage of the actuator controlled via an excitation signal based on a specific model, the excitation signal comprising at least one sinusoidal measurement signal component for measuring the impedance of the actuator;
providing a measurement current indicative of a time-dependent current of the actuator controlled via the excitation signal;
estimating, using a first matched filter unit, a voltage amplitude and an associated phase of the measurement signal component arising at the actuator using the measurement voltage provided and the specific model of the excitation signal;
estimating, using a second matched filter unit, a current amplitude and an associated phase of the measurement signal component arising at the actuator using the measurement current provided and the specific model of the excitation signal; and
calculating the impedance of the actuator on the basis of the estimated voltage amplitude, the estimated associated phase, the estimated current amplitude and the estimated associated phase.
